(19) United States
(12) Patent Application Publication
(10) Pub. No.: US 2025/0192105 A1
(43) Pub. Date: Jun. 12, 2025

(54) 3D STACK PACKAGE STRUCTURE

(71) Applicant: Powerchip Semiconductor Manufacturing Corporation, Hsinchu (TW)

(72) Inventors: Yu-Chang Lin, Hsinchu (TW); Pei-Rong Ni, Hsinchu (TW); Chun-Lin Lu, Hsinchu City (TW); Sheng Chieh Lin, Hsinchu City (TW); Yung-Hsiang Chang, Hsinchu (TW)

(73) Assignee: Powerchip Semiconductor Manufacturing Corporation, Hsinchu (TW)

(21) Appl. No.: 18/539,239

(22) Filed: Dec. 13, 2023

(30) Foreign Application Priority Data
Dec. 6, 2023 (TW) 112147402

(51) Int. Cl. H01L 25/065; H01L 23/00; H01L 23/31; H01L 23/498

(52) U.S. Cl. CPC H01L 25/0657; H01L 23/3142; H01L 23/49822; H01L 23/49838; H01L 24/08; H01L 24/16; H01L 2224/08146; H01L 2224/08235; H01L 2224/16227; H01L 2224/16235; H01L 2225/06513; H01L 2225/06517; H01L 2225/06541; H01L 2924/183; H01L 2924/30205

(57) ABSTRACT

A 3D stack package structure includes a first chip, a second chip, a through-silicon via (TSV), and a multi-layer protective structure. The second chip is bonded to the first chip. The second chip includes an interconnect structure composed of multiple metal layers and a plurality of vias respectively connecting upper and lower layers of the multiple metal layers. The TSV extends through the second chip. The multi-layer protective structure is disposed within the second chip and surrounds the TSV. The multi-layer protective structure includes: multiple protective layers, each having an opening for passage of the TSV; and a plurality of sealing rings, respectively connecting upper and lower layers of the multiple protective layers and surrounding the TSV.

### CROSS-REFERENCE TO RELATED APPLICATION

This application claims the priority benefit of Taiwan application serial no. 112147402, filed on Dec. 6, 2023. The entirety of the above-mentioned patent application is hereby incorporated by reference herein and made a part of this specification.

### BACKGROUND

### Technical Field

The disclosure relates to a 3D stack package structure, and in particular to a 3D stack package structure including a through-silicon via (TSV) that is completely surrounded by a multi-layer protective structure.

### Description of Related Art

Through-silicon via (TSV) is a technology that integrates multiple chips into a single stack three-dimensional integrated circuit.

However, a through-silicon via may suffer structural damage due to moisture entry, stress damage, or electrostatic discharge (ESD), thereby reducing reliability of the through-silicon via. Therefore, to protect the structure of the through-silicon via and maintain the reliability of the through-silicon via is an objective for which efforts are being made.

### SUMMARY

The disclosure provides a 3D stack package structure which can be applied in wafer-on-wafer (WoW) packaging and can effectively protect the structure of a through-silicon via from structural damage due to moisture entry, stress damage or electrostatic discharge.

A 3D stack package structure according to the disclosure includes a first chip, a second chip, a through-silicon via (TSV), and a multi-layer protective structure. The second chip is bonded to the first chip. The second chip includes an interconnect structure composed of multiple metal layers and a plurality of vias that respectively connect upper and lower layers of the multiple metal layers. The through-silicon via extends through the second chip. The multi-layer protective structure is disposed within the second chip and surrounds the through-silicon via. The multi-layer protective structure includes multiple protective layers and a plurality of sealing rings. The multiple protective layers each have an opening for passage of the through-silicon via. The plurality of sealing rings respectively connect upper and lower layers of the multiple protective layers and surround the through-silicon via.

In one embodiment of the disclosure, the plurality of sealing rings and the plurality of vias in the interconnect structure are formed in the same process.

In one embodiment of the disclosure, the multiple protective layers and the multiple metal layers in the interconnect structure are formed in the same process.

In one embodiment of the disclosure, the multiple protective layers are in direct contact with the through-silicon via.

In one embodiment of the disclosure, the first chip includes a first redistribution layer, the second chip includes a second redistribution layer, and the through-silicon via connects the first redistribution layer and the second redistribution layer.

In one embodiment of the disclosure, the first chip is hybrid bonded to the second chip.

In one embodiment of the disclosure, the first chip is bonded to the second chip by oxide-oxide bonding.

In one embodiment of the disclosure, the second chip may further include a device isolation structure, and the through-silicon via extends through the device isolation structure.

The disclosure further provides a 3D stack package structure including a first chip, a plurality of second chips, a through-silicon via (TSV), and a plurality of multi-layer protective structures. The first chip includes a first substrate and a first semiconductor structure formed on the first substrate. The plurality of second chips each include a second substrate and a second semiconductor structure formed on the second substrate. The second semiconductor structure includes an interconnect structure composed of multiple metal layers and a plurality of vias that respectively connect upper and lower layers of the multiple metal layers. The plurality of second chips are bonded to each other. The first semiconductor structure of the first chip is bonded to the second semiconductor structure of the second chip. The through-silicon via extends through all of the second chips. The plurality of multi-layer protective structures are respectively disposed within the plurality of second chips and surround the through-silicon via. Each multi-layer protective structure includes multiple protective layers and a plurality of sealing rings. The multiple protective layers each have an opening for passage of the through-silicon via. The plurality of sealing rings respectively connect upper and lower layers of the multiple protective layers and surround the through-silicon via.

In another embodiment of the disclosure, the plurality of sealing rings in each second chip and the plurality of vias in the interconnect structure are formed in the same process.

In another embodiment of the disclosure, the multiple protective layers in each second chip and the multiple metal layers in the interconnect structure are formed in the same process.

In another embodiment of the disclosure, the multiple protective layers in each second chip are in direct contact with the through-silicon via.

In another embodiment of the disclosure, the first chip includes a first redistribution layer, the outermost second chip among the plurality of second chips includes a second redistribution layer, and the through-silicon via connects the first redistribution layer and the second redistribution layer.

In another embodiment of the disclosure, the plurality of second chips are bonded to each other by oxide-oxide bonding.

In another embodiment of the disclosure, the first chip is bonded to the second chip by oxide-oxide bonding.

In another embodiment of the disclosure, each second chip may further include a device isolation structure, and the through-silicon via extends through the device isolation structure.

Based on the above, the 3D stack package structure according to the disclosure includes the protective layer and the sealing ring that may completely surround the through-silicon via and effectively protect the structure of the through-silicon via from structural damage due to moisture entry, stress damage or electrostatic discharge, thereby maintaining the reliability of the through-silicon via.

To make the aforementioned more comprehensible, several embodiments accompanied with drawings are described in detail as follows.

### BRIEF DESCRIPTION OF DRAWINGS

FIG. 1A is a cross-sectional view of a 3D stack package structure according to a first embodiment of the disclosure.

FIG. 1B is a partial plan view of the structure of FIG. 1A in the first embodiment.

FIG. 1C is a partially enlarged schematic perspective view of FIG. 1A.

FIG. 2 is a cross-sectional view of a 3D stack package structure according to a second embodiment of the disclosure.

FIG. 3 is a cross-sectional view of a 3D stack package structure according to a third embodiment of the disclosure.

FIG. 4 is a cross-sectional view of a 3D stack package structure according to a fourth embodiment of the disclosure.

FIG. 5 is a cross-sectional view of a 3D stack package structure according to a fifth embodiment of the disclosure.

FIG. 6A to FIG. 6E are schematic cross-sectional views of a manufacturing process flow of a 3D stack package structure according to a sixth embodiment of the disclosure.

### DESCRIPTION OF EMBODIMENTS

The disclosure may be understood by referring to the following detailed description taken in conjunction with the accompanying drawings. It should be noted that, to facilitate understanding and simplify the drawings, many of the drawings in the disclosure only depict a part of a structure, and certain elements in the drawings are not drawn according to actual scales. The number and size of each element in the drawings are for illustrative purposes only, and are not intended to limit the scope of the disclosure. Directional terms mentioned herein, such as “upper” and “lower”, are only directions with reference to the drawings, and are not intended to limit the disclosure. In the following, the term “including” and the like should be interpreted as “including but not limited to”. Although the terms such as “first” and “second” are used herein to indicate different elements, components, regions, layers and/or blocks, these elements, components, regions, layers and/or blocks are not to be limited by these terms. These terms are only used to distinguish one element, component, region, layer or block, from another element, component, region, layer or block. The term “or” as used herein encompasses all of the associated listed items.

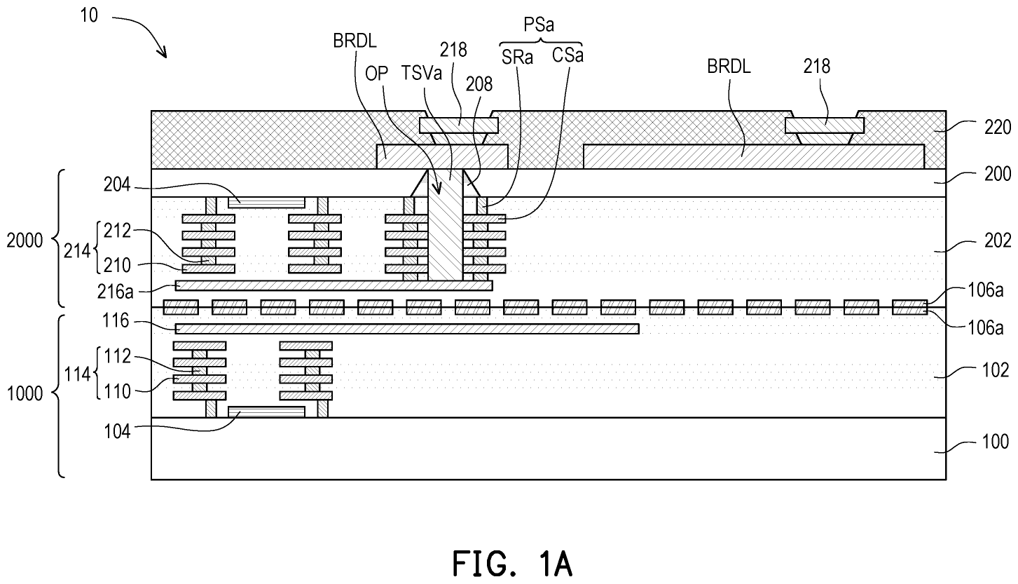

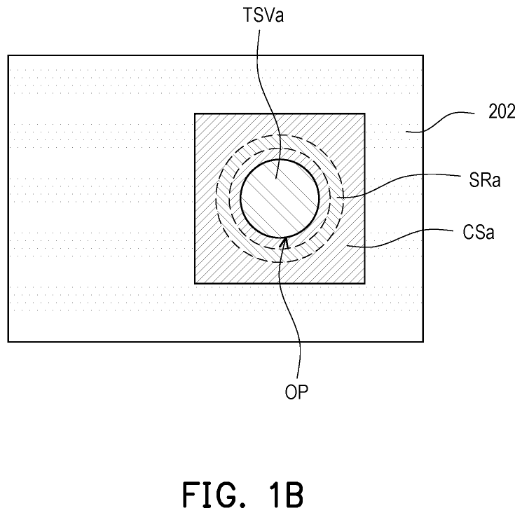

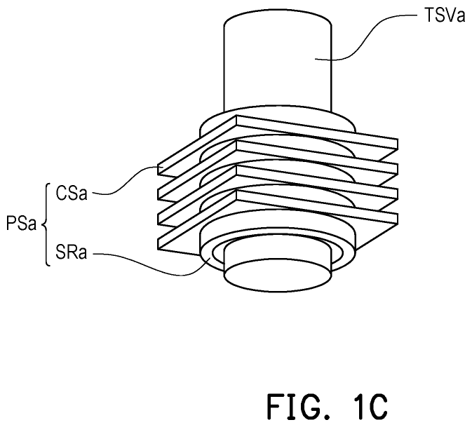

FIG. 1A is a cross-sectional view of a 3D stack package structure 10 according to a first embodiment of the disclosure.

Referring to FIG. 1A, the 3D stack package structure 10 of the first embodiment includes: a first chip 1000, a second chip 2000, a first through-silicon via TSVa, and a first multi-layer protective structure PSa. The second chip 2000 is bonded to the first chip 1000. The term “chip” as mentioned above refers to, in a broad sense, a wafer that has undergone a front-end circuit process or a die obtained by cutting in a semiconductor apparatus. Accordingly, in one embodiment, the first chip 1000 and the second chip 2000 may be regarded as a first wafer and a second wafer, and the rest can be deduced accordingly. The second chip 2000 includes a second interconnect structure 214 that is composed of multiple second metal layers 210 and a plurality of second vias 212 respectively connecting upper and lower layers of the multiple second metal layers 210. The first through-silicon via TSVa extends through the second chip 2000. The first multi-layer protective structure PSa is disposed within the second chip 2000 and surrounds the first through-silicon via TSVa. The first multi-layer protective structure PSa includes multiple first protective layers CSa and a plurality of first sealing rings SRa. The first sealing rings SRa respectively connect upper and lower layers of the multiple first protective layers CSa and surround the first through-silicon via TSVa. The multiple first protective layers CSa each have an opening OP for passage of the first through-silicon via TSVa, as shown in the partial plan view of FIG. 1B and the perspective view of FIG. 1C.

In FIG. 1B, the first protective layer CSa has a square outer shape, the opening OP has a circular outline, and a region between the dashed circles indicates a position of the first sealing ring SRa. The first sealing ring SRa surrounds at a distance from the first through-silicon via TSVa. In FIG. 1C, the first multi-layer protective structure PSa surrounds the first through-silicon via TSVa, and a portion of the first through-silicon via TSVa not surrounded is disposed within the second chip 2000. The opening OP may be of a size equivalent to or slightly larger than that of the first through-silicon via TSVa. The opening OP may also be of a size smaller than a predetermined size of the first through-silicon via TSVa as long as an etching process can extend through the first protective layer CSa. In this case, the first protective layer CSa is in direct contact with the first through-silicon via TSVa.

Referring still to FIG. 1A, the interconnect structure 214 and the first multi-layer protective structure PSa of the second chip 2000 may be made of a conductive material such as titanium, tantalum, platinum, copper, gold, aluminum, titanium nitride, or a combination of the foregoing. However, the disclosure is not limited thereto. The plurality of first sealing rings SRa and the multiple first protective layers CSa in the first multi-layer protective structure PSa may be made of the same or different materials. The multiple second metal layers 210 and the plurality of second vias 212 may be made of the same or different materials. The first through-silicon via TSVa may be made of a conductive material such as copper, tungsten, polycrystalline silicon, or a combination of the foregoing. However, the disclosure is not limited thereto.

The second chip 2000 may further include components such as a second substrate 200, a second dielectric layer 202, a second redistribution layer (RDL) 216a, and a second semiconductor device 204. However, the disclosure is not limited thereto. Since the second chip 2000 and the first chip 1000 are bonded to each other, the second chip 2000 is illustrated as being inverted in FIG. 1A. The second interconnect structure 214 is formed within the second dielectric layer 202 located on the second substrate 200. The second redistribution layer 216a is formed on the interconnect structure 214 and connected to the first through-silicon via TSVa. The first through-silicon via TSVa extends through the second substrate 200. The second substrate 200 may further include a second device isolation structure 208. The first through-silicon via TSVa may be formed by etching through the second device isolation structure 208 and continuously etching through the second dielectric layer 202. In FIG. 1A, one first sealing ring SRa in the first protective structure PSa is connected to the second redistribution layer 216a. The second semiconductor device 204 is disposed on the second substrate 200, and is connected to other components such as the second redistribution layer 216a through the second interconnect structure 214.

Referring still to FIG. 1A, the first chip 1000 may further include a first substrate 100, a first dielectric layer 102, a first semiconductor device 104, a first interconnect structure 114, and a first redistribution layer 116. The first dielectric layer 102 and the first semiconductor device 104 are formed on the first substrate 100. The first interconnect structure 114 is composed of multiple first metal layers 110 and a plurality of first vias 112 respectively connecting upper and lower layers of the multiple first metal layers 110. The first interconnect structure 114 may be made of a conductive material such as titanium, tantalum, platinum, copper, gold, aluminum, titanium nitride, or a combination of the foregoing. However, the disclosure is not limited thereto. The first redistribution layer 116 is disposed on the first interconnect structure 114. Although FIG. 1A does not show a relationship between the first redistribution layer 116 and the first interconnect structure 114 below the first redistribution layer 116, it should be understood that the first redistribution layer 116 makes it possible to change original positions of contacts in the first interconnect structure 114 according to needs, so that the first interconnect structure 114 can be electrically connected to the second semiconductor device 204 of the second chip 2000. Accordingly, the first redistribution layer 116 and the first interconnect structure 114 below the first redistribution layer 116 are connected through a circuit in other cross sections.

In the 3D stack package structure 10 of the first embodiment, since the first chip 1000 and the second chip 2000 can be bonded by hybrid bonding, a first metal bonding part 106a is formed on a bonding surface of each of the first chip 1000 and the second chip 2000. By the bonding between the first metal bonding part 106a of the first chip 1000 and the first metal bonding part 106a of the second chip 2000 as well as the bonding between the first dielectric layer 102 of the first chip 1000 and the second dielectric layer 202 of the second chip 2000, the hybrid bonding mentioned above is achieved. However, the disclosure is not limited thereto, and different bonding processes may be used in other embodiments.

Referring still to FIG. 1A, the 3D stack package structure 10 of the first embodiment may further include a back-side redistribution layer BRDL, a pad 218, and an insulating layer 220. The back-side redistribution layer BRDL is disposed on the second substrate 200 relative to the second semiconductor device 204, and the first through-silicon via TSVa may be connected to the back-side redistribution layer BRDL. The pad 218 is disposed on the back-side redistribution layer BRDL. The insulating layer 220 covers the back-side redistribution layer BRDL, and partially exposes a surface of the pad 218 for connection with other apparatuses or circuit boards (not shown).

In some embodiments, the first substrate 100 and the second substrate 200 may be made of silicon or other suitable materials. However, the disclosure is not limited thereto. The other suitable materials mentioned above include, but not limited to, silicon germanium, silicon carbide, and gallium arsenide. Materials of the insulating layer 220, the first dielectric layer 102 and the second dielectric layer 202 include, but not limited to, silicon oxide, silicon oxynitride, silicon nitride, high dielectric constant dielectric metal oxide (such as hafnium oxide, zirconium oxide, hafnium zirconium oxide, titanium oxide, tantalum oxide, yttrium oxide, lanthanum oxide, and aluminum oxide), or a combination of the foregoing. The first semiconductor device 104 and the second semiconductor device 204 may include an active device, a passive device, or a combination thereof. Examples thereof include a transistor, a diode, a capacitor, a resistor, and an inductor. The back-side redistribution layer BRDL, the pad 218, the first redistribution layer 116 and the second redistribution layer 216a may be made of a conductive material such as tungsten, titanium, tantalum, platinum, copper, gold, aluminum, titanium nitride, or a combination of the foregoing. However, the disclosure is not limited thereto.

Referring still to FIG. 1A, the plurality of first sealing rings SRa in the first multi-layer protective structure PSa and the plurality of second vias 212 in the second interconnect structure 214 may be formed by the same process. For example, one second via 212 and one first sealing ring SRa may be formed at the same time by the same photomask process. Thus, the second via 212 and the first sealing ring SRa are formed on the same plane and are made of the same material. Accordingly, no additional lithography and etching processes are required, thereby simplifying the process and reducing the cost in the present embodiment.

Referring still to FIG. 1A, the multiple first protective layers CSa in the first multi-layer protective structure PSa and the multiple second metal layers 210 in the second interconnect structure 214 may be formed by the same process. For example, one first protective layer CSa and one second metal layer 210 may be formed at the same time by the same photomask process. Thus, the first protective layer CSa and the second metal layer 210 are formed on the same plane and are made of the same material. Accordingly, no additional lithography and etching processes are required, thereby simplifying the process and reducing the cost in the present embodiment.

In the present embodiment, the first through-silicon via TSVa is completely surrounded by the first protective layer CSa and the first sealing ring SRa, except for a region that extends through the second substrate 200 and is surrounded by the second substrate 200. Thus, the first multi-layer protective structure PSa may effectively protect the first through-silicon via TSVa from structural damage due to moisture entry, stress damage or electrostatic discharge, thereby maintaining the reliability of the first through-silicon via TSVa.

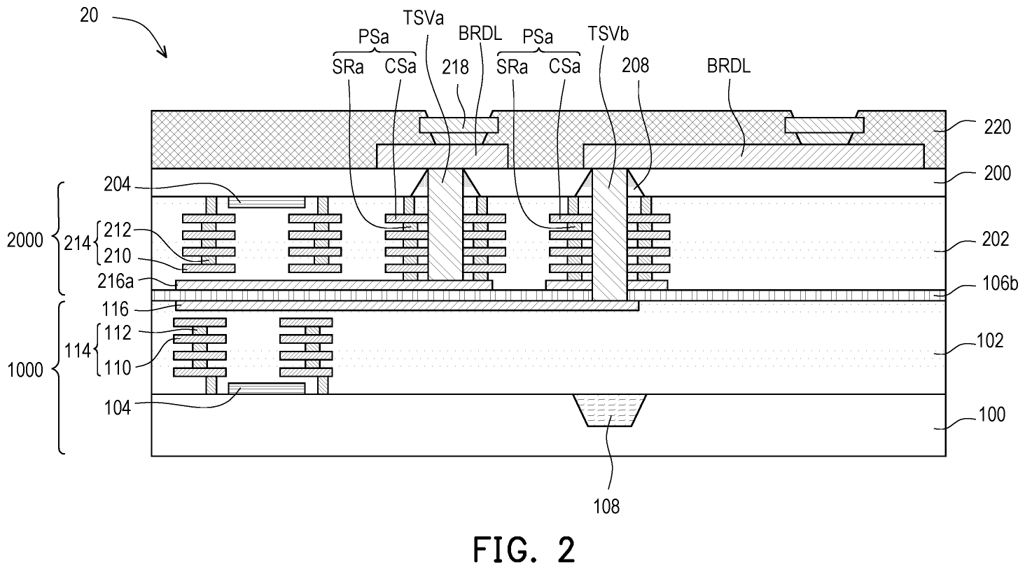

FIG. 2 is a cross-sectional view of a 3D stack package structure 20 according to a second embodiment of the disclosure, in which the same reference numerals as those in the first embodiment denote the same or similar portions and components, and the related content of the same or similar portions and components can be understood with reference to the description of the first embodiment and will not be described again.

Specifically, the second embodiment differs from the first embodiment mainly in that the second chip 2000 of the present embodiment further includes a second through-silicon via TSVb and a second multi-layer protective structure PSb. The second through-silicon via TSVb extends through the second chip 2000 and is connected to the first redistribution layer 116 in the first chip 1000. The second multi-layer protective structure PSb is disposed within the second chip 2000 and surrounds the second through-silicon via TSVb. The second multi-layer protective structure PSb includes multiple second protective layers CSb and a plurality of second sealing rings SRb. The second sealing rings SRb respectively connect upper and lower layers of the multiple second protective layers CSb and surround the second through-silicon via TSVb.

Referring still to FIG. 2, the 3D stack package structure 20 may include a first oxide layer 106b disposed on a bonding surface between the first chip 1000 and the second chip 2000. Thus, oxide-oxide bonding can be achieved by the first oxide layer 106b. In the present embodiment, the second through-silicon via TSVb extends through the first oxide layer 106b to be connected to the first redistribution layer 116. The first substrate 100 may further include a first device isolation structure 108.

It should be understood that one of ordinary skill in the art may adjust the specific number and spatial configuration of through-silicon vias according to product requirements, and the disclosure is not limited thereto.

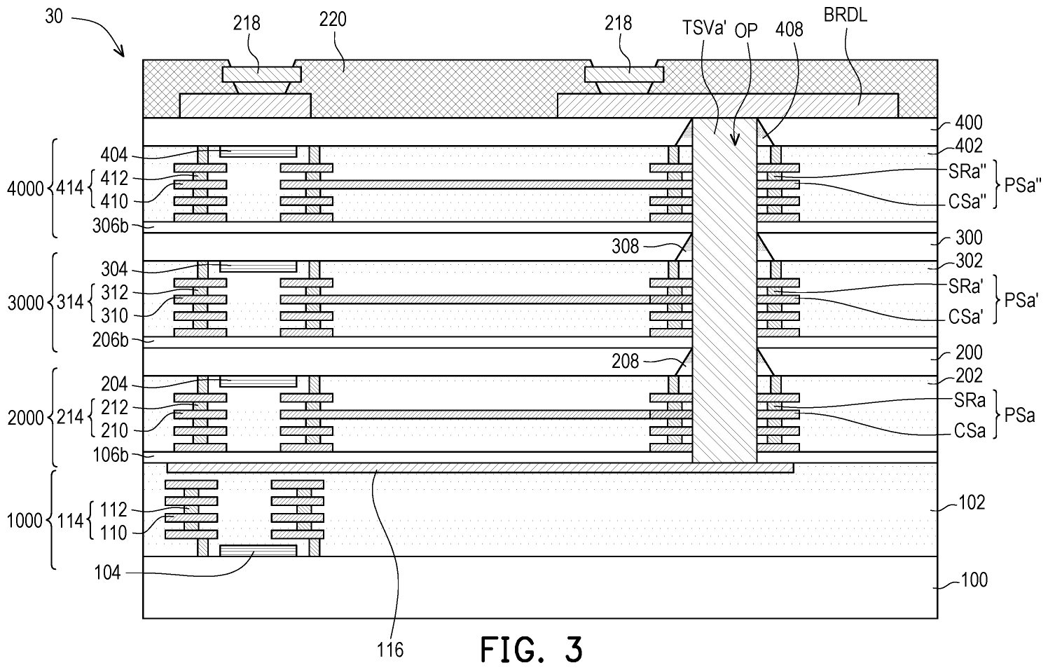

FIG. 3 is a cross-sectional view of a 3D stack package structure 30 according to a third embodiment of the disclosure, in which the same reference numerals as those in the first embodiment denote the same or similar portions and components, and the related content of the same or similar portions and components can be understood with reference to the description of the first embodiment and will not be described again.

Referring to FIG. 3, the 3D stack package structure 30 of the third embodiment includes the first chip 1000, the second chip 2000, a third chip 3000, and a fourth chip 4000. The structures of the first chip 1000 and the second chip 2000 have been detailed in the first embodiment. The third chip 3000 includes components such as a third substrate 300, a third dielectric layer 302, a third semiconductor device 304, a third interconnect structure 314, and a first multi-layer protective structure PSa′. The third interconnect structure 314 is composed of multiple third metal layers 310 and a plurality of third vias 312 respectively connecting upper and lower layers of the multiple third metal layers 310. The other components are similar to those of the second chip 2000. The fourth chip 4000 includes components such as a fourth substrate 400, a fourth dielectric layer 402, a fourth semiconductor device 404, a fourth interconnect structure 414, and a first multi-layer protective structure PSa″. The fourth interconnect structure 414 is composed of multiple fourth metal layers 410 and a plurality of fourth vias 412 respectively connecting upper and lower layers of the multiple fourth metal layers 410. The other components are similar to those of the second chip 2000. In the present embodiment, the second chip 2000, the third chip 3000 and the fourth chip 4000 have the same structure such as, for example, the same semiconductor structure on a substrate. Accordingly, the second chip 2000, the third chip 3000 and the fourth chip 4000 may be regarded as a plurality of identical chips. However, the disclosure is not limited thereto. In another embodiment, there may be a difference between the second chip 2000, the third chip 3000, and the fourth chip 4000. For example, the third semiconductor device 304 and the fourth semiconductor device 404 may be different devices, and the rest can be deduced accordingly.

In FIG. 3, a first through-silicon via TSVa′ extends through the second chip 2000, the third chip 3000 and the fourth chip 4000, and connects the back-side redistribution layer BRDL and the first redistribution layer 116. The first multi-layer protective structure PSa, the first multi-layer protective structure PSa′ and the first multi-layer protective structure PSa″ are respectively disposed within the second chip 2000, the third chip 3000 and the fourth chip 4000, and surround the first through-silicon via TSVa′. The first multi-layer protective structure PSa includes multiple first protective layers CSa and a plurality of first sealing rings SRa; the first multi-layer protective structure PSa′ includes multiple first protective layers CSa′ and a plurality of first sealing rings SRa′; the first multi-layer protective structure PSa″ includes multiple first protective layers CSa″ and a plurality of first sealing rings SRa″. Like the first protective layer CSa, the first protective layer CSa′ and the first protective layer CSa″ may both have the opening OP for passage of the first through-silicon via TSVa′. The first sealing rings SRa respectively connect upper and lower layers of the multiple first protective layers CSa and surround the first through-silicon via TSVa′; the first sealing rings SRa′ respectively connect upper and lower layers of the multiple first protective layers CSa′ and surround the first through-silicon via TSVa′; the first sealing rings SRa″ respectively connect upper and lower layers of the multiple first protective layers CSa″ and surround the first through-silicon via TSVa′.

It should be understood that one of ordinary skill in the art may adjust the specific number of stacked chips according to product requirements, and the disclosure is not limited thereto.

Referring still to FIG. 3, the second metal layer 210 may be connected to the first protective layer CSa, the third metal layer 310 may be connected to the first protective layer CSa′, and the fourth metal layer 410 may be connected to the first protective layer CSa″. However, the disclosure is not limited thereto. In another embodiment, the second metal layer 210 may not be connected to the first protective layer CSa, and the rest can be deduced accordingly.

In the present embodiment, the first chip 1000, the second chip 2000, the third chip 3000 and the fourth chip 4000 may be bonded to each other by oxide-oxide bonding. The 3D stack package structure 30 may further include the first oxide layer 106b, a second oxide layer 206b, and a third oxide layer 306b each disposed on a bonding surface between two chips. The third substrate 300 may further include a third device isolation structure 308 and the fourth substrate 400 may further include a fourth device isolation structure 408 for use in an etching process for forming the first through-silicon via TSVa′.

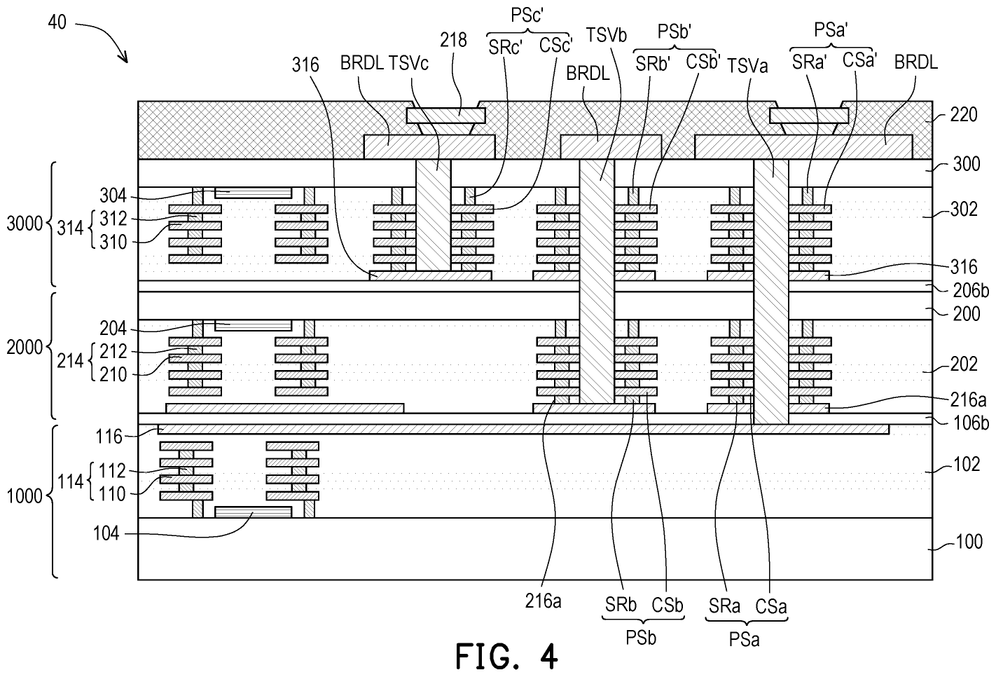

FIG. 4 is a cross-sectional view of a 3D stack package structure 40 according to a fourth embodiment of the disclosure, in which the same reference numerals as those in the third embodiment denote the same or similar portions and components, and the related content of the same or similar portions and components can be understood with reference to the description of the third embodiment and will not be described again.

Specifically, the present embodiment differs from the third embodiment in that the number of chips is three, the second through-silicon via TSVb is additionally provided in the second chip 2000 and the third chip 3000, and a third through-silicon via TSVc is additionally provided in the third chip 3000. The second through-silicon via TSVb is surrounded by the second multi-layer protective structure PSb and a second multi-layer protective structure PSb′. The third through-silicon via TSVc is surrounded by a third multi-layer protective structure PSc′. The second multi-layer protective structure PSb includes the second sealing ring SRb and the second protective layer CSb; the second multi-layer protective structure PSb′ includes a second sealing ring SRb′ and a second protective layer CSb′; the third multi-layer protective structure PSc′ includes a third sealing ring SRc′ and a third protective layer CSc′.

In FIG. 4, the second chip 2000 may further include the second redistribution layer 216a, and the third chip 3000 may further include a third redistribution layer 316. The first through-silicon via TSVa connects the first redistribution layer 116, the second redistribution layer 216a, the third redistribution layer 316 and the back-side redistribution layer BRDL. The second through-silicon via TSVb connects the second redistribution layer 216a, the third redistribution layer 316 and the back-side redistribution layer BRDL. The third through-silicon via TSVc connects the third redistribution layer 316 and the back-side redistribution layer BRDL.

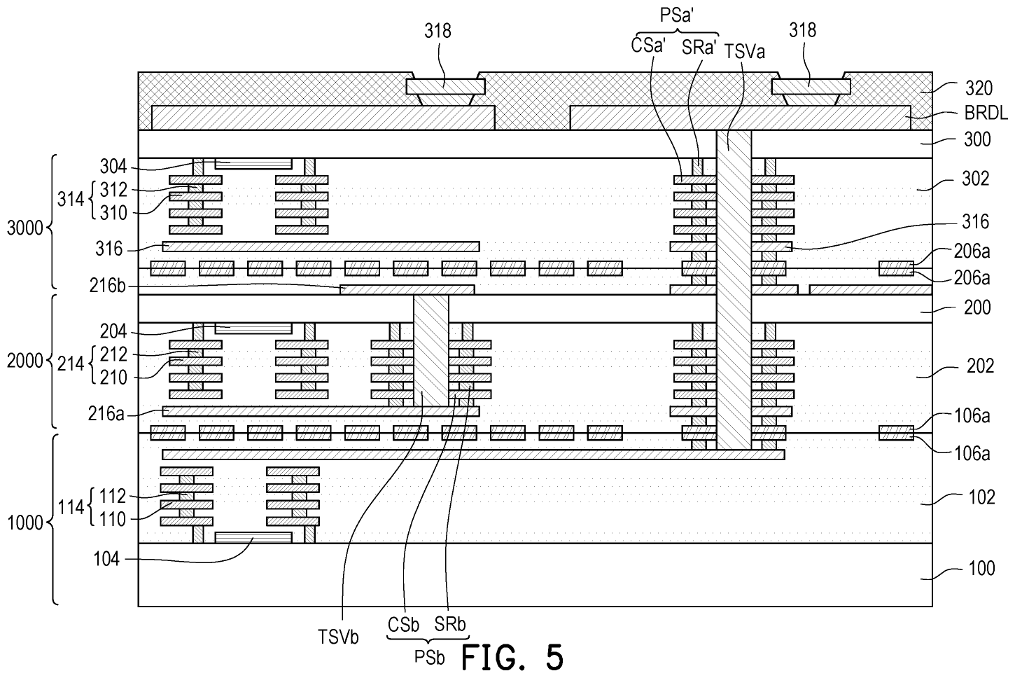

FIG. 5 is a cross-sectional view of a 3D stack package structure 50 according to a fifth embodiment of the disclosure, in which the same reference numerals as those in the third embodiment denote the same or similar portions and components, and the related content of the same or similar portions and components can be understood with reference to the description of the third embodiment and will not be described again.

Specifically, the present embodiment differs from the third embodiment in that the number of chips is three, and the second chip 2000 of the present embodiment may include the second through-silicon via TSVb and the second multi-layer protective structure PSb. The second multi-layer protective structure PSb is disposed within the second chip 2000 and surrounds the second through-silicon via TSVb. The second multi-layer protective structure PSb includes the second sealing ring SRb and the second protective layer CSb.

In FIG. 5, the second chip 2000 further includes two second redistribution layers, namely the second redistribution layer 216a and a second redistribution layer 216b. The second redistribution layer 216a is disposed on one side of the second substrate 200, and the second redistribution layer 216b is disposed on a side close to the first chip 1000. The third chip 3000 includes the third redistribution layer 316 close to the second chip 2000. The second through-silicon via TSVb connects the second redistribution layer 216a and the second redistribution layer 216b. The first through-silicon via TSVa connects the first redistribution layer 116, the second redistribution layer 216a, the second redistribution layer 216b, the third redistribution layer 316 and the back-side redistribution layer BRDL.

Referring still to FIG. 5, the first chip 1000, the second chip 2000 and the third chip 3000 are bonded together by hybrid bonding. Thus, the first metal bonding part 106a may be provided on the bonding surface between the first chip 1000 and the second chip 2000, and a second metal bonding part 206a may be provided on a bonding surface between the second chip 2000 and the third chip 3000. Since the hybrid bonding process is an existing technology, no details will be described thereof.

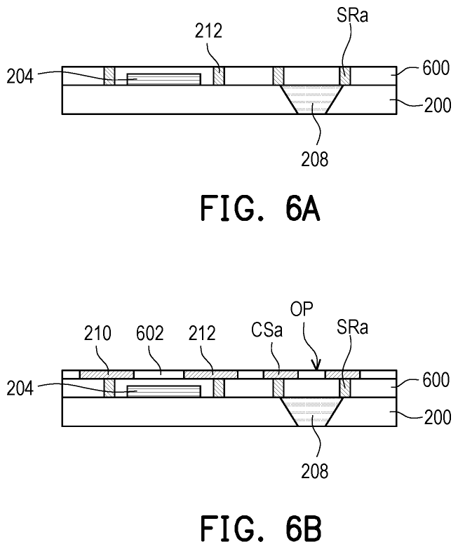

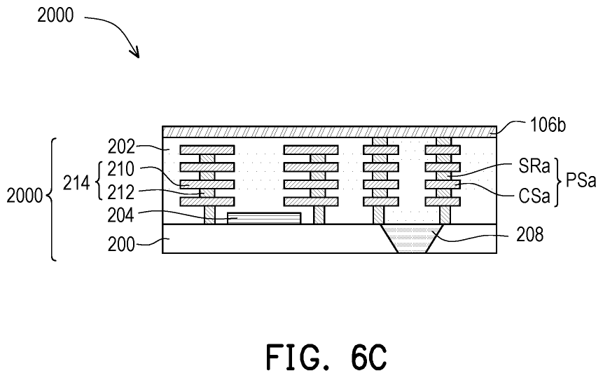

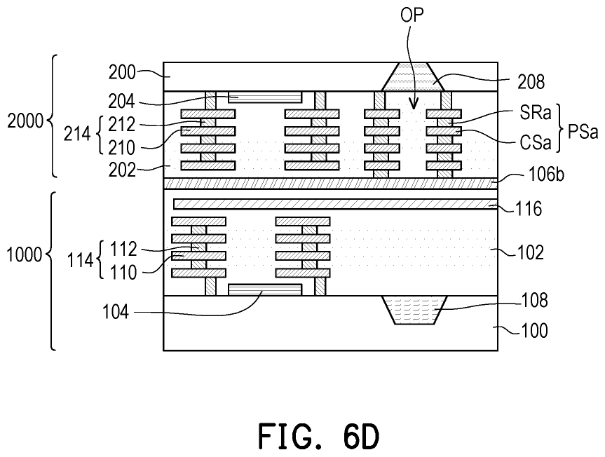

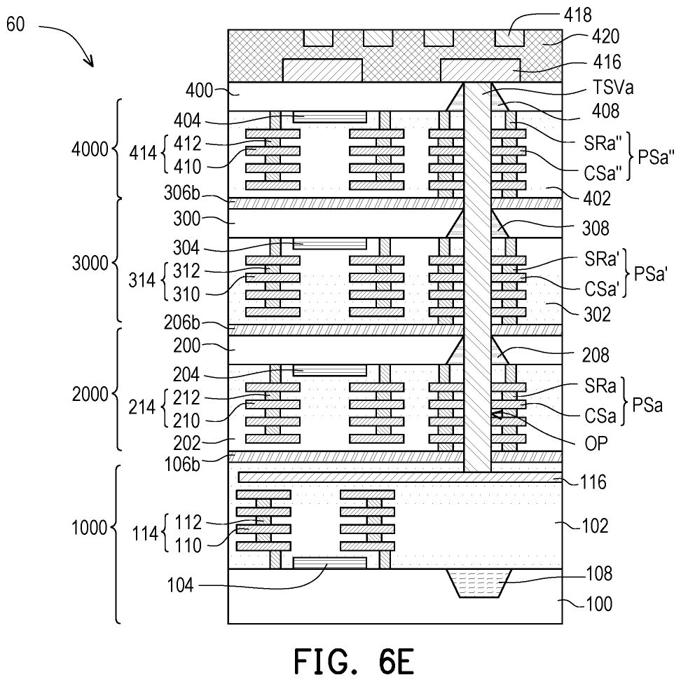

FIG. 6A to FIG. 6E are schematic cross-sectional views of a manufacturing process flow of a 3D stack package structure 60 according to a sixth embodiment of the disclosure, in which the same reference numerals as those in the third embodiment denote the same or similar portions and components, and the related content of the same or similar portions and components can be understood with reference to the description of the third embodiment and will not be described again.

Referring first to FIG. 6A, the second semiconductor device 204 is formed on the second substrate 200 including the second element isolation structure 208. Then, a dielectric layer 600 is formed and covers the second semiconductor device 204. Next, the second via 212 and the first sealing ring SRa are formed in the dielectric layer 600. The first sealing ring SRa may be formed directly above the second device isolation structure 208. The second via 212 may be electrically connected to the second semiconductor device 204. In the second via 212 and the first sealing ring SRa, an opening may be formed by the same photomask process, followed by filling of a metal material. Accordingly, the first sealing ring SRa and the second via 212 are formed on the same plane and made of the same material, and no additional process is required to form the first sealing ring SRa.

Next, referring to FIG. 6B, another dielectric layer 602 is formed on the dielectric layer 600. Then, the second metal layer 210 and the first protective layer CSa are formed in the dielectric layer 602. In the second metal layer 210 and the first protective layer CSa, an opening may be formed by the same photomask process, followed by filling of a metal material. Accordingly, the second metal layer 210 and the first protective layer CSa are formed on the same plane and made of the same material, and no additional process is required to form the first protective layer CSa.

Then, please refer to FIG. 6C. By repeating the above steps according to the device design, the second interconnect structure 214 is formed composed of multiple second metal layers 210 and a plurality of second vias 212 that respectively connect the upper and lower layers of the multiple second metal layers 210. Meanwhile, the first protective structure PSa is formed composed of multiple first protective layers CSa and a plurality of first sealing rings SRa that respectively connect the upper and lower layers of the multiple first protective layers CSa. The second dielectric layer 202 in FIG. 6C is a structure composed of multiple dielectric layers (such as the dielectric layer 600 and the dielectric layer 602 in FIG. 6B). After that, the first oxide layer 106b is formed on the second dielectric layer 202, thereby forming the second chip 2000.

Next, referring to FIG. 6D, the second chip 2000 in FIG. 6C is turned over, and is bonded to the first chip 1000 by, for example, oxide-oxide bonding. The first chip 1000 can be understood by referring to the first embodiment, except that the first chip 1000 of the present embodiment does not include the first metal bonding part (106a), and the first device isolation structure 108 is provided within the first substrate 100.

Then, referring to FIG. 6E, by repeating the above steps according to product requirements, a plurality of chips such as the first chip 1000, the second chip 2000, the third chip 3000 and the fourth chip 4000 are bonded. The structures of the third chip 3000 and the fourth chip 4000 can be understood by referring to the third embodiment. After that, the first through-silicon via TSVa is formed extending through the second chip 2000, the third chip 3000 and the fourth chip 4000. The first through-silicon via TSVa may be formed by, for example, continuously etching through the fourth chip 4000, the third chip 3000 and the second chip 2000 with the opening OP as an alignment reference. Since the second device isolation structure 208, the third device isolation structure 308 and the fourth device isolation structure 408 are all made of silicon oxide similarly to the second dielectric layer 202, the third dielectric layer 302, and the fourth dielectric layer 402, it is possible to obtain a through hole extending through the fourth chip 4000, the third chip 3000 and the second chip 2000 by continuous etching. Then, a conductive material is formed in the through hole, thereby forming the first through-silicon via TSVa. After that, the back-side redistribution layer BRDL is formed on the fourth chip 4000 that is the outermost layer. Then, an insulating layer 420 and a pad 418 are formed. Other subsequent processes may be performed and a description thereof will be omitted.

To sum up, in the 3D stack package structure according to the disclosure, the through-silicon via is completely surrounded by the protective layer and the sealing ring in a plane and a vertical direction. Thus, the structure of the through-silicon via can be effectively protected from structural damage due to moisture entry, stress damage or electrostatic discharge, thereby maintaining the reliability of the through-silicon via. Since the protective layer and the sealing ring are formed in the same process as the metal layer and the via in the chip, respectively, no additional photomask process is required. Thus, the process is simplified and the cost is reduced.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A 3D stack package structure, comprising:
a first chip;
a second chip, bonded to the first chip and comprising an interconnect structure, the interconnect structure being composed of multiple metal layers and a plurality of vias that respectively connect upper and lower layers of the multiple metal layers;
a through-silicon via, extending through the second chip; and
a multi-layer protective structure, disposed within the second chip and surrounding the through-silicon via, wherein the multi-layer protective structure comprises:
multiple protective layers, each having an opening for passage of the through-silicon via; and
a plurality of sealing rings, respectively connecting upper and lower layers of the multiple protective layers and surrounding the through-silicon via.

2. The 3D stack package structure according to claim 1, wherein
the plurality of sealing rings and the plurality of vias in the interconnect structure are formed in a same process.

3. The 3D stack package structure according to claim 1, wherein
the multiple protective layers and the multiple metal layers in the interconnect structure are formed in a same process.

4. The 3D stack package structure according to claim 1, wherein
the multiple protective layers are in direct contact with the through-silicon via.

5. The 3D stack package structure according to claim 1, wherein
the first chip comprises a first redistribution layer, the second chip comprises a second redistribution layer, and the through-silicon via connects the first redistribution layer and the second redistribution layer.

6. The 3D stack package structure according to claim 1, wherein
the first chip is hybrid bonded to the second chip.

7. The 3D stack package structure according to claim 1, wherein
the first chip is bonded to the second chip by oxide-oxide bonding.

8. The 3D stack package structure according to claim 1, wherein
the second chip further comprises a device isolation structure, and the through-silicon via extends through the device isolation structure.

9. A 3D stack package structure, comprising:
a first chip, comprising a first substrate and a first semiconductor structure formed on the first substrate;
a plurality of second chips, each comprising a second substrate and a second semiconductor structure formed on the second substrate, wherein the second semiconductor structure comprises an interconnect structure composed of multiple metal layers and a plurality of vias that respectively connect upper and lower layers of the multiple metal layers, the plurality of second chips are bonded to each other, and the first semiconductor structure of the first chip is bonded to the second semiconductor structure of the second chip;
a through-silicon via, extending through the plurality of second chips; and
a plurality of multi-layer protective structures, respectively disposed within the plurality of second chips and surrounding the through-silicon via, wherein each of the multi-layer protective structures comprises:
multiple protective layers, each having an opening for passage of the through-silicon via; and
a plurality of sealing rings, respectively connecting upper and lower layers of the multiple protective layers and surrounding the through-silicon via.

10. The 3D stack package structure according to claim 9, wherein
the plurality of sealing rings in each of the second chips and the plurality of vias in the interconnect structure are formed in a same process.

11. The 3D stack package structure according to claim 9, wherein
the multiple protective layers in each of the second chips and the multiple metal layers in the interconnect structure are formed in a same process.

12. The 3D stack package structure according to claim 9, wherein
the multiple protective layers in each of the second chips are in direct contact with the through-silicon via.

13. The 3D stack package structure according to claim 9, wherein
the first chip comprises a first redistribution layer, the outermost second chip among the plurality of second chips comprises a second redistribution layer, and the through-silicon via connects the first redistribution layer and the second redistribution layer.

14. The 3D stack package structure according to claim 9, wherein
the plurality of second chips are bonded to each other by oxide-oxide bonding.

15. The 3D stack package structure according to claim 9, wherein
the first chip is bonded to the second chip by oxide-oxide bonding.

16. The 3D stack package structure according to claim 9, wherein
each of the second chips further comprises a device isolation structure, and the through-silicon via extends through the device isolation structure.
